(19) United States
(12) Patent Application Publication
(10) Pub. No.: US 2008/0237765 A1
(43) Pub. Date: Oct. 2, 2008

(54) IMAGE SENSOR WITH THE ABILITY TO DETECT ALL COLORS AT EACH PIXEL

(76) Inventor: Victor Chepettchouk, Richmond Hill (CA)

Correspondence Address: VICTOR CHEPETTCHOUK, 46 GRAND OAK DRIVE, RICHMND HILL, ON, L4E-3Z9, CA

(21) Appl. No.: 12/135,159

(22) Filed: Jun. 7, 2008

(51) Int. Cl. H01L 31/10

(52) U.S. Cl. 257/432; 257/E31.053

(57) ABSTRACT

An image sensor with the ability to detect a different light wavelength at each pixel, due to a change of physical characteristics of material under light with different wavelength illumination.

### FIELD OF INVENTION

The present invention relates to an image sensor that is capable of capturing all colors by each pixel, and provide complete color information to signal processing chip.

### BACKGROUND OF INVENTION

Currently image sensors implemented CMOS or CCD technology and color Bayer filter, where each pixel detects light intensity. Bayer type image sensor is capable of recording one color at each pixel, instead of all colors.

Foveon image sensor has three layers of pixels based on silicon physical property, that light with different wavelengths penetrate to different silicon depths, and using CMOS technology, when different sensors layer detects different colors. Foveon sensor is difficult to manufacture, and the sensor has significant noise level in low light conditions.

Presented image sensor detects all colors on each pixel, using change of dielectric properties of materials under light with different wavelengths irradiation, and does not require multilayer layout.

As was described in U.S. Pat. No. 6,862,095 B2, the dielectric constant is a function of light wavelength. Formula is provided in line 55 and explanation in line 65 on page 2, section “Description of the Preferred Embodiments”. Where dielectric constant is a function of light energy E (=hv). And physical process is described in line 65 on pages 2 and 3.

### BRIEF DESCRIPTION OF THE INVENTION

The present invention relates to an image sensor with the ability to detect all colors at each pixel. Each pixel includes dielectric/semiconductor material, and light with different wavelengths will change dielectric constant to a different value.

Signals from pixels will be transferred to signal processing chip, where color information will be extracted from image sensor signal.

Signals pre-processing could be performed directly in the image sensor chip, as currently available in existing image sensors.

CMOS or CCD image sensors layout could be used for the proposed image sensor.

### BRIEF DESCRIPTION OF THE DRAWINGS

FIG. 1 is a general view of pixel and interconnections;

FIG. 2 is an example of general schematic to detect changes in dielectric properties of material;

FIG. 3 is a general layout of imaging sensor with external frequency generator;

FIG. 5 is a general layout of imaging sensor with incorporated schematic for detection dielectric properties changes.

### DETAILED DESCRIPTION OF THE INVENTION

Image sensor uses the property of material to change dielectric constant under light with different wavelength.

And ∈ (dielectric constant) is a function of light energy E (=hv), when light with different wavelengths will change dielectric properties of materials in different ways. As result, light with different wavelengths will result in different signal frequency at each pixel. Processing chip will detect different frequency from pixel, and assign correspondent color. See FIG. 1.

Change in dielectric constant could be detected using different electronics approaches, such as using oscillators, multivibrators, or band pass filters. Direct color detection image sensor can use CMOS or CCD image sensor layout. And when light reaches pixel, it will change dielectric/semiconductor properties, particularly ∈—dielectric constant. Dielectric with n or p doped will perform as a semiconductor.

And

$$C = \frac{ɛ A}{d} \qquad ( 1 )$$

Where

∈—dielectric constant

A—plate area

d—plate separation

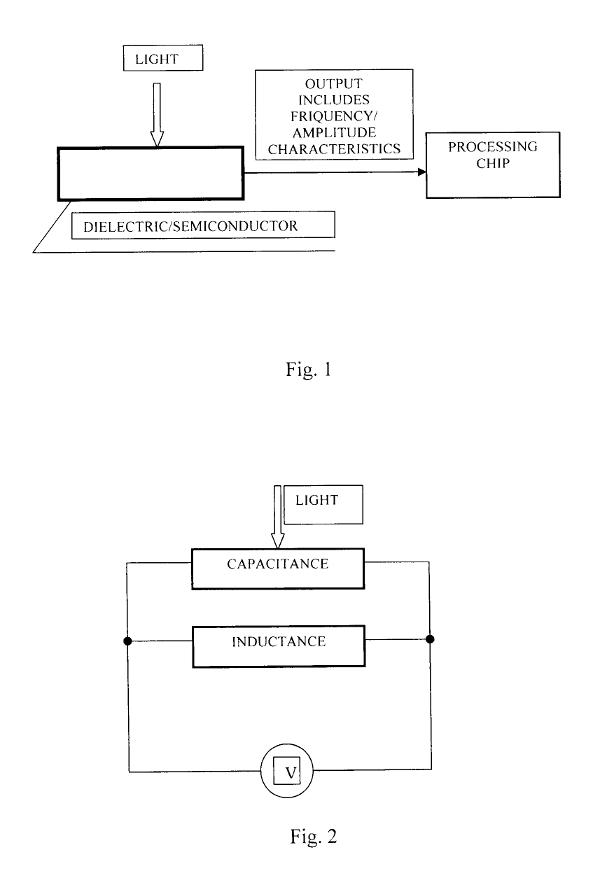

FIG. 2 shows simplified oscillator schematic.

Where oscillator frequency will be

$${f}_{o} = \frac{{ω}_{o}}{2 π} = \frac{1}{2 π \sqrt{LC}} \qquad ( 2 )$$

Where frequency will be the function of dielectric constant ∈.

And ∈ (dielectric constant) is a function of light energy ∈ (=hv), when light with different wavelengths will change dielectric properties of materials in different ways. As result, light with different wavelengths will result in different signal frequency at each pixel. Processing chip will receive different frequency signals from pixel, analyze frequency characteristics, and will assign colors to correspondent pixels.

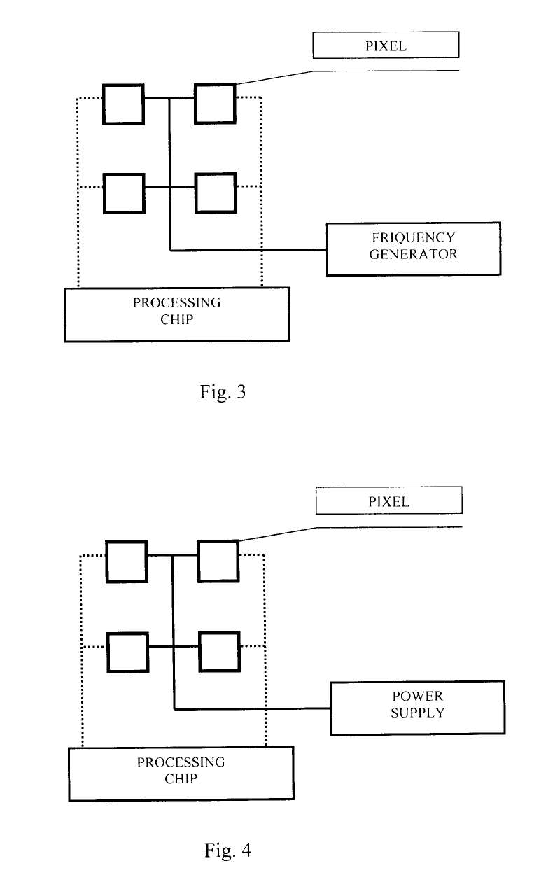

Detection of dielectric constant and correspondent frequency can be performed using common generator, when frequency generator supplies signal to common line, and processing chip analyze the signal from each pixel as shown on FIG. 3.

Or each pixel can have its own oscillator or multivibrator circuit and signal from each pixel circuit will be sent to processing chip as shown on FIG. 4.

Any type of schematics could be used, which can be applicable for detection of change in dielectric constant.

Image sensor can combine light intensity and light wavelengths detection into one circuit, when signal processing chip can analyze amplitude and frequency data from each pixel and extract light intensity and light color information.

Some pixels can have different color filters, and located in active and/or inactive imaging sensor area, and used for calibration and adjustment of color information by processing chip.

What is claimed is:

1. An image sensor with color detection, by using physical property of dielectric materials, or semiconductors to change dielectric property constant differently under light with different wavelengths.

2. The image sensor according to claim 1 wherein said sends signal to processing chip, and processing chip analyze signals including signal frequency, or signal frequency and amplitude from each pixel and extract color and light intensity information.

3. The image sensor according to claim 1 wherein said can combines light wavelengths and light intensity detection function in one circuit.

4. The image sensor according to claim 1 wherein said can have oscillator or multivibrators circuit at each pixel.

5. The image sensor according to claim 1 wherein said can receive broadband frequency signal from frequency generator to each pixel, when supplied signal will change frequency amplitude characteristics, and will be analyzed in processing chip.

6. The image sensor according to claim 1 wherein said can have any type of schematics, which can be applicable for detection of change in dielectric constant.

7. The image sensor according to claim 1 wherein said can have pixels covered by different color filters, and such pixels can be located on active, inactive or both imaging sensor areas. Signals from such pixels can be used for calibration and adjustment of color information, and generation of complete image.

8. The image sensor according to claim 1 wherein said can implement analog to digital converter, which sends signal to processing chip.
